(19) United States
(12) Patent Application Publication
(10) Pub. No.: US 2015/0311271 A1
(43) Pub. Date: Oct. 29, 2015

(54) LANDSIDE EMBEDDED INDUCTOR FOR FANOUT PACKAGING

(71) Applicant: QUALCOMM Incorporated, San Diego, CA (US)

(72) Inventors: Mete ERTURK, San Diego, CA (US); Ravindra Vaman SHENOY, Dublin, CA (US); Kwan-yu LAI, Campbell, CA (US); Donald William KIDWELL, JR., Campbell, CA (US); Jitae KIM, Mountain View, CA (US); Jon Bradley LASITER, Stockton, CA (US)

(21) Appl. No.: 14/451,462

(22) Filed: Aug. 5, 2014

Related U.S. Application Data
(60) Provisional application No. 61/983,447, filed on Apr. 23, 2014.

(51) Int. Cl. H01L 49/02; H01F 27/24

(52) U.S. Cl. CPC H01L 28/10; H01F 27/24

(57) ABSTRACT

One or more high-inductance, high-quality factor (Q) three-dimensional inductors, for example, solenoid or toroid inductors with small form factors, are provided in an integrated circuit package, such as an integrated fanout package.

### CROSS-REFERENCE TO RELATED APPLICATIONS

The present Application for Patent claims the benefit of U.S. Provisional Application No. 61/983,447, entitled “LANDSIDE EMBEDDED INDUCTOR FOR FANOUT PACKAGING,” filed Apr. 23, 2014, assigned to the assignee hereof, and expressly incorporated herein by reference in its entirety.

### FIELD OF DISCLOSURE

Various embodiments described herein relate to integrated circuit packaging, and more particularly, to inductors in integrated circuit packaging.

### BACKGROUND

In communication devices, various attempts have been made to integrate digital, analog, radio-frequency (RF) and power management components in single integrated circuit packages, also called system-on-a-chip (SOC) packages. A typical SOC package may include various discrete components such as capacitors or inductors mounted in the same package that also houses semiconductor circuits on one or more dies. However, high-inductance off-chip inductors typically occupy substantial surface areas or volumes when implemented in conventional SOC packages. Moreover, conventional inductor layouts in SOC packages usually suffer resistive losses in redistribution layers forming the interconnect between circuit blocks within the SOC and off-chip inductors. For a typical state-of-the-art SOC, the added series resistance could be as high as 120 mΩ. There has been growing interest in a type of integrated circuit packaging, called integrated fanout packaging, which was believed to provide purported benefits of improved performance over conventional forms of SOC packages. An inductor with an inductance value of 5 nH or more, typically required for RF or power management applications, would require a large amount of surface area or volume, thereby necessitating a large form factor for the package, which would be unacceptable in chip packages for mobile communication devices with stringent form-factor limitations.

### SUMMARY

Exemplary embodiments are directed to an integrated circuit package including one or more high-inductance, high quality factor (Q) inductors with a small form factor in the landside region of the package, and method of making the same.

In an embodiment, a device comprises: an interconnect layer having a first surface and a second surface opposite each other; one or more dies on the first surface of the interconnect layer; one or more balls on the second surface of the interconnect layer, said one or more balls each having a height perpendicular to the second surface of the interconnect layer and one or more outer surfaces, the outer surfaces of at least some of said one or more balls and the second surface of the interconnect layer forming a landside region; and one or more three-dimensional inductors comprising one or more solenoids occupying at least a portion of the height of said one or more balls and one or more magnets within the landside region.

In another embodiment, a device comprises: an interconnect layer having a first surface and a second surface opposite each other; one or more dies on the first surface of the interconnect layer; one or more balls on the second surface of the interconnect layer, said one or more balls each having a height perpendicular to the second surface of the interconnect layer and one or more outer surfaces, the outer surfaces of at least some of said one or more balls and the second surface of the interconnect layer forming a landside region; and one or more three-dimensional inductors comprising one or more toroids occupying at least a portion of the height of said one or more balls and one or more magnets within the landside region.

In yet another embodiment, a method of making an integrated circuit package comprises the steps of: forming a first patterned conductive layer on a panel; forming a first dielectric layer on the first patterned conductive layer; forming a magnet on the first dielectric layer; forming a second dielectric layer on the magnet; and forming a second patterned conductive layer on the second dielectric layer, wherein the first patterned conductive layer, the second patterned conductive layer and the magnet together constitute at least a portion of a three-dimensional inductor.

### BRIEF DESCRIPTION OF THE DRAWINGS

The accompanying drawings are presented to aid in the description of embodiments and are provided solely for illustration of the embodiments and not limitations thereof.

FIG. 1 is a sectional view of an integrated fanout package with a system-on-a-chip (SOC) die, a post passivation interconnect (PPI) layer, ball grid array (BGA) balls, and a landside region in which one or more inductors may be implemented in an embodiment.

FIG. 2 is a sectional view of the integrated fanout package of FIG. 1 with two closely coupled three-dimensional inductors each having a solenoid configuration implemented in the landside region of the package in an embodiment.

FIG. 3 is a more detailed perspective view of two closely coupled solenoid inductors implemented in the landside region of the integrated fanout package of FIG. 2.

FIG. 4 is a more detailed side view of an embodiment of one of the solenoid inductors of FIG. 3 having a substantially rectangular side section and a single layer of magnetic material.

FIG. 5 is a more detailed side view of an embodiment of one of the solenoid inductors of FIG. 3 having a substantially rectangular side section and two layers of magnetic material.

FIG. 6 is a perspective view of another embodiment in which the inductor in the landside region of the integrated fanout package comprises a toroid inductor.

FIGS. 7A and 7B are perspective and top views, respectively, of yet another embodiment in which the inductor comprises a toroid inductor surrounding one of the BGA balls in the integrated fanout package.

FIGS. 8A-8C illustrate a process of making an inductor for implementation in an integrated fanout package in an embodiment.

### DETAILED DESCRIPTION

Aspects of the disclosure are described in the following description and related drawings directed to specific embodiments of the disclosure. Alternate embodiments may be devised without departing from the scope of the claims. Additionally, well known elements will not be described in detail or will be omitted so as not to obscure the relevant details of the disclosure.

The word “exemplary” is used herein to mean “serving as an example, instance, or illustration.” Any embodiment described herein as “exemplary” is not necessarily to be construed as preferred or advantageous over other embodiments. Likewise, the term “embodiments” does not require that all embodiments include the discussed feature, advantage or mode of operation.

The terminology used herein is for the purpose of describing particular embodiments only and is not intended to be limiting of embodiments of the disclosure. As used herein, the singular forms “a,” “an,” and “the,” are intended to include the plural forms as well, unless the context clearly indicates otherwise. It will be further understood that the terms “comprises,” “comprising,” “includes,” or “including,” when used herein, specify the presence of stated features, integers, steps, operations, elements, or components, but do not preclude the presence or addition of one or more other features, integers, steps, operations, elements, components, or groups thereof. Moreover, it is understood that the word “or” has the same meaning as the Boolean operator “OR,” that is, it encompasses the possibilities of “either” and “both” and is not limited to “exclusive or” (“XOR”), unless expressly stated otherwise.

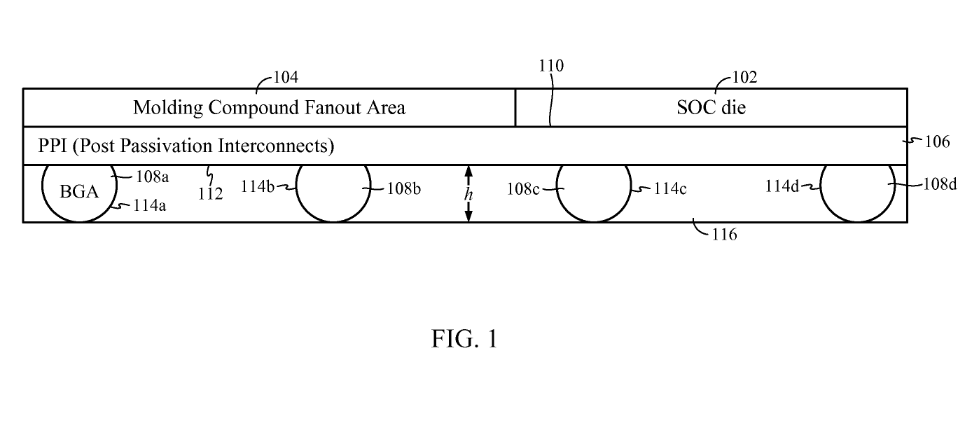

FIG. 1 is a sectional view of an integrated fanout package having a system-on-a-chip (SOC) die 102, a molding compound fanout area 104, a post passivation interconnect (PPI) layer 106 and a plurality of ball grid array (BGA) balls 108a, 108b, 108c and 108d. In the configuration shown in FIG. 1, the SOC die 102 and the molding compound fanout area 104 are disposed on a first surface 110 of the PPI layer 106, whereas the BGA balls 108a, 108b, 108c and 108d are disposed on a second surface 112 of the PPI layer 106. The first and second surfaces 110 and 112 of the PPI layer 106 are opposite each other. Each of the BGA balls 108a, 108b, 108c and 108d has a predefined height h, which may be 200 μm or less, for example. As shown FIG. 1, the BGA balls 108a, 108b, 108c and 108d have outer surfaces 114a, 114b, 114c and 114d, respectively. The outer surfaces 114c and 114d of the BGA balls 108c and 108d and the second surface 112 of the PPI layer 106 define a space called a landside region 116, in which one or more inductors may be implemented according to various embodiments.

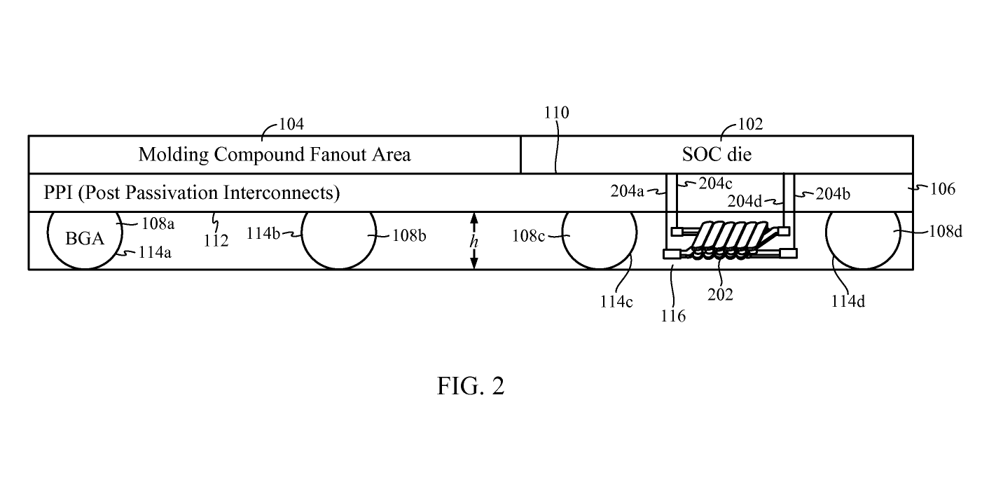

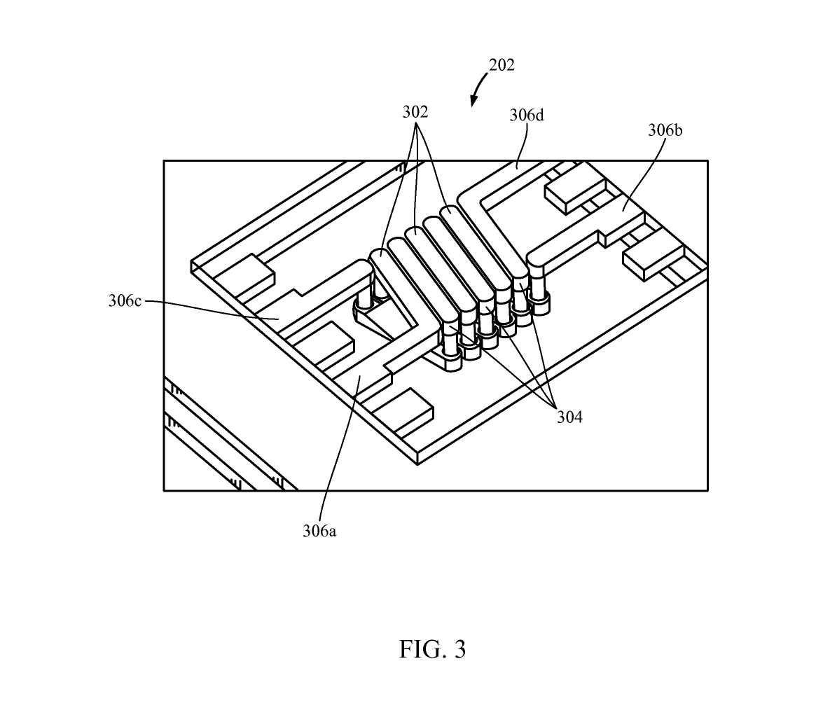

FIG. 2 is a sectional view of the integrated fanout package of FIG. 1 with two closely coupled three-dimensional inductors 202 comprising two closely coupled spirals implemented in the landside region 116 of the package according to an embodiment of the disclosure. In the embodiment shown in FIG. 2, each of the three-dimensional inductors 202 has a solenoid configuration, which will be described in more detailed below with reference to FIGS. 3-5. The two closely coupled three-dimensional solenoid inductors 202 may be implemented as switching DC-DC regulators for power management of the circuitry in the SOC die 102, for example, or for other applications.

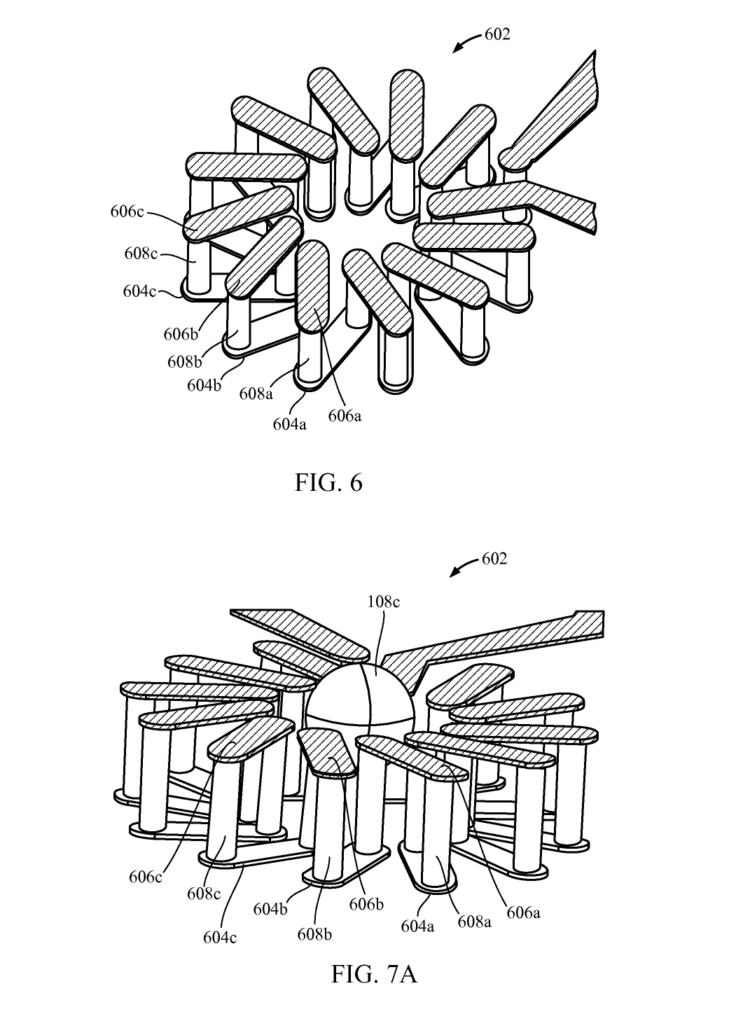

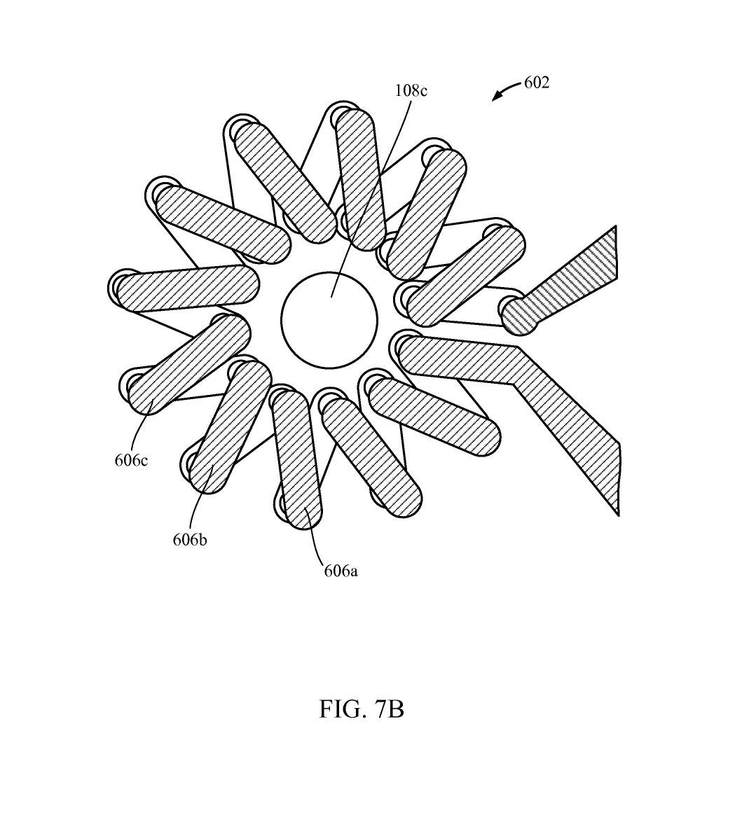

In another embodiment, a single three-dimensional solenoid inductor may be implemented in the landside region 116 of the integrated fanout package. Alternatively, the three-dimensional inductor 202 may have a toroid configuration in the landside region 116 of the integrated fanout package, which will be described in more detail below with reference to FIG. 6. In yet another alternative embodiment, the three-dimensional inductor 202 may have a toroid configuration centered about one of the BGA balls in the package, which will be described in more detail below with reference to FIGS. 7A-7B. Inductors of various shapes and sizes may be implemented for a variety of applications in connection with digital, analog, RF or power management circuitry in the SOC die 102.

In the embodiment shown in FIG. 2, the closely coupled three-dimensional solenoid inductors 202 are disposed in the landside region 116 directly opposite the SOC die 102, separated by the PPI layer 106. In this embodiment, four conductors 204a, 204b, 204c and 204d are connected between the circuitry in the SOC die 102 and the four terminals of the two closely coupled solenoid inductors 202, details of which are shown in the perspective view of FIG. 3. Referring to FIG. 3, the two closely coupled solenoid inductors 202 comprise a first three-dimensional solenoid inductor 302 and a second three-dimensional solenoid inductor 304 coupled with each other turn by turn. Such closely coupled solenoid inductors 302 and 304 may be implemented for various applications, such as switching DC-DC regulators or out-of-phase switched mode regulators for power management, for example, or for various other applications.

In FIG. 3, the first three-dimensional solenoid inductor 302 has a first terminal 306a and a second terminal 306b, whereas the second three-dimensional solenoid inductor 304 has a first terminal 306c and a second terminal 306d. In an embodiment, the terminals 306a and 306b of the first solenoid inductor 302 are connected to the circuitry in the SOC die 102 through conductors 204a and 204b as shown in FIG. 2, respectively. Similarly, the terminals 306c and 306d of the second solenoid inductor 304 in FIG. 3 are connected to the circuitry in the SOC die 102 through conductors 204c and 204d as shown in FIG. 2, respectively.

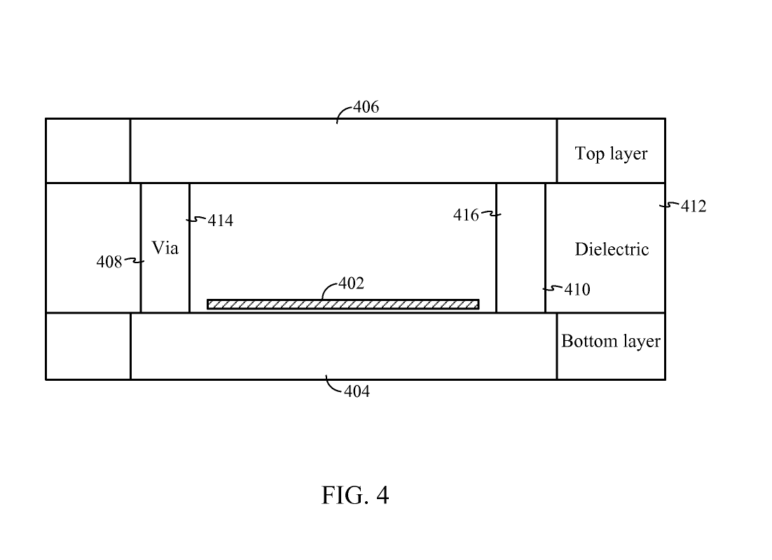

FIG. 4 is a more detailed side view of an embodiment showing a single turn of either the solenoid inductor 302 or the solenoid inductor 304 of FIG. 3 having a substantially rectangular side section and a single layer of magnet 402. In this embodiment, the single turn of the solenoid inductor having a substantially rectangular side section is formed of a bottom conductive layer 404, a top conductive layer 406, and side conductors 408 and 410. In an embodiment, a dielectric 412 is provided between the top and bottom conductive layers 404 and 406. In a further embodiment, the side conductors 408 and 410 are provided through holes or vias 414 and 416, respectively, in the dielectric 412. In the embodiment shown in FIG. 4, the single layer of magnet 402 is disposed on the bottom conductive layer 404 within the solenoid.

In an embodiment, the single layer of magnet 402 comprises cobalt-zirconium-tantalum (CZT). In another embodiment, the single layer of magnet 402 comprises nickel-iron (NiFe). Other magnetic materials may also be used to increase the magnetic flux of the inductor within the scope of the disclosure. The single layer of magnet 402, such as CZT, may be sputtered after the plating of bottom traces of the solenoid, a single turn of which is shown as the bottom layer 404 in FIG. 4, for example.

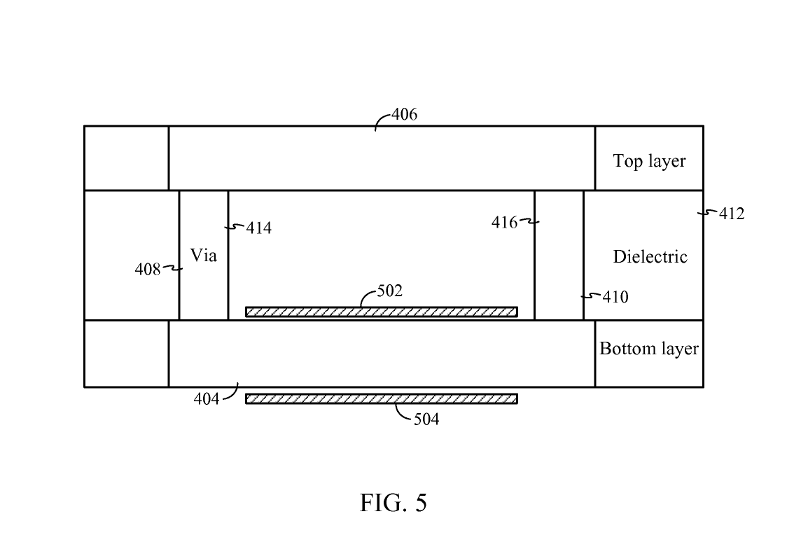

FIG. 5 is a more detailed side view of another embodiment showing a single turn of either the solenoid inductor 302 or the solenoid inductor 304 of FIG. 3 having a substantially rectangular side section and two layers of magnets 502 and 504. Like FIG. 4, the single turn of the solenoid inductor having a substantially rectangular side section is formed of a bottom conductive layer 404, a top conductive layer 406, and side conductors 408 and 410. In an embodiment, a dielectric 412 is provided between the top and bottom conductive layers 404 and 406. In a further embodiment, the side conductors 408 and 410 are provided through holes or vias 414 and 416, respectively, in the dielectric 412. In the embodiment shown in FIG. 5, two layers of magnets 502 and 504 are disposed opposite each other on the bottom conductive layer 404. In an embodiment, the two layers of magnets 502 and 504 comprise CZT. In another embodiment, the layers of magnets 502 and 504 comprise NiFe. Other magnetic materials may also be used to increase the magnetic flux of the inductor within the scope of the disclosure.

In an embodiment, the layer of magnet 504 outside the solenoid may be sputtered before plating the bottom traces of the solenoid, one turn of which is shown as the bottom conductive layer 404 in FIG. 5. In a further embodiment, the layer of magnet 502 inside the solenoid may be sputtered after plating the bottom traces of the solenoid. In an alternative embodiment, one or more layers of magnetic materials such as CZT or NiFe may be provided on the top conductive layer 406, inside or outside the solenoid. In yet another alternative embodiment, one or more layers of magnetic materials such as CZT or NiFe may be provided as parallel layers to one or both of the side conductors 408 and 410, inside or outside the solenoid. Magnetic materials of various types and shapes may be implemented to increase the magnetic flux of the solenoid within the scope of the disclosure.

FIG. 6 is a perspective view of another embodiment in which the inductor in the landside region of the integrated fanout package comprises a toroid inductor 602. Similar to the solenoid configurations described above with respect to FIGS. 3-5, the toroid configuration as shown in FIG. 6 has a substantially rectangular side section with bottom conductive traces 604a, 604b, 604c, . . . , top conductive traces 606a, 606b, 606c, . . . , and side conductors 608a, 608b, 608c, . . . . In an embodiment, one or more layers of magnetic materials such as CZT or NiFe may be implemented along the bottom conductive traces 604a, 604b, 604c, inside or outside the toroid inductor 602, in manners similar to those shown in FIG. 4 or 5 and described above. Alternatively, one or more layers of magnetic materials may be provided along the top conductive traces 606a, 606b, 606c, . . . in a similar manner. In another alternative, one or more layers of magnetic materials may be provided along the side conductors 608a, 608b, 608c, . . . to increase the magnetic flux of the toroid inductor. Again, magnetic materials of various types and shapes may be implemented to increase the magnetic flux of the toroid within the scope of the disclosure.

FIGS. 7A and 7B are perspective and top views, respectively, of yet another embodiment in which the toroid inductor 602 surrounds one of the BGA balls in the integrated fanout package, for example, BGA ball 108c beneath the PPI layer 106 opposite the SOC die 102 as shown in FIG. 1 or 2. Referring to the embodiment shown in FIGS. 7A-B, the toroid is centered about the BGA ball 108c, thereby efficiently utilizing the volume in the landside region 116 around the BGA ball 108c. Alternatively, the toroid inductor 602 may be implemented entirely in the landside region 116 between BGA balls 108c and 108d, for example, within the space otherwise occupied by the three-dimensional solenoid inductors 202 as shown in FIG. 2. Three-dimensional inductors of other geometries may also be implemented with magnetic materials to increase their inductances in the landside region of an integrated fanout package within the scope of the disclosure.

Three-dimensional inductors such as solenoid or toroid inductors are expected to result in superior performance in terms of higher inductance and higher Q over conventional planar spiral inductors implemented in conventional chip packages due to enhanced magnetic efficiency with respect to magnetic field convergence. Furthermore, the implementation of one or more layers of magnetic materials in three-dimensional inductors such as solenoid or toroid inductors further boosts inductance density, thereby achieving high inductance while maintaining a small form factor.

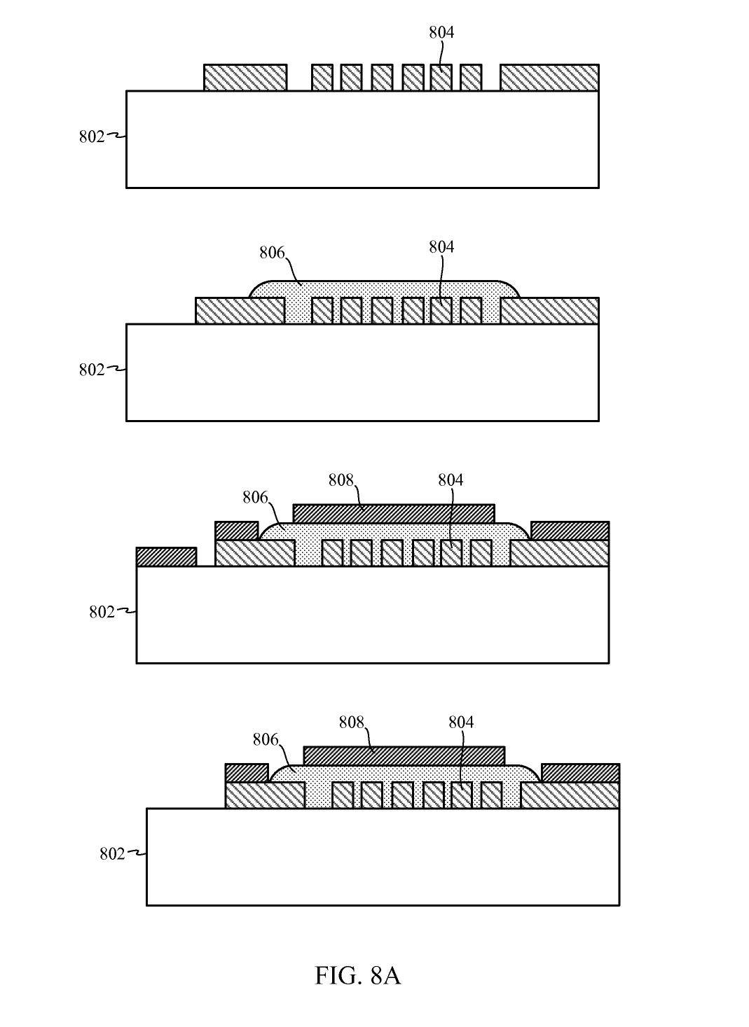

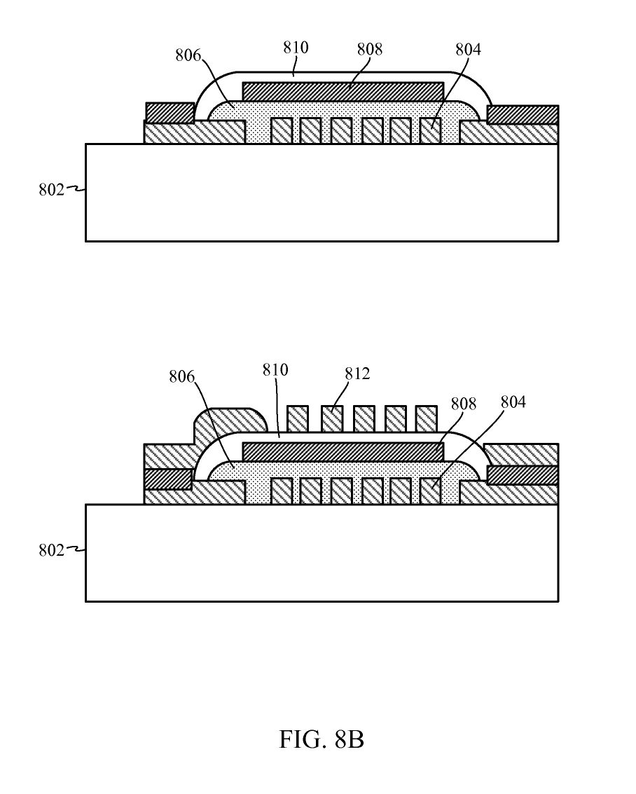

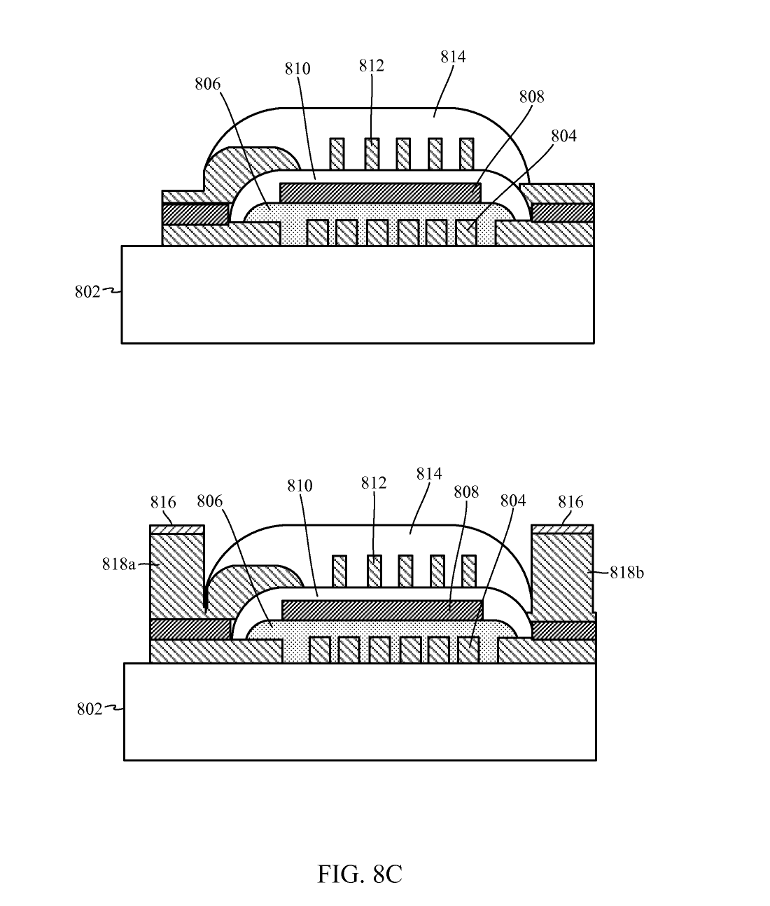

FIGS. 8A-8C illustrate an embodiment of a method of making three-dimensional inductors. In FIG. 8A, a panel 802 is provided as a substrate for the fabrication of the inductors. In an embodiment, the panel comprises a wafer, for example, a silicon wafer typically used in semiconductor fabrication processes. Alternatively, the panel 802 may comprise a glass, ceramic or other type of substrate. In an embodiment, multiple inductors may be fabricated on the panel 802, which may be a conventional silicon, ceramic or glass wafer or substrate, in a batch process to reduce cost. After the inductors are fabricated on the panel 802, the panel is polished, thinned or released such that the inductors meet the height and form factor requirements for placement in the landside region 116 of the integrated fanout package as shown in FIG. 1 or 2.

Referring to FIG. 8A, a first patterned conductive layer 804 is formed on the panel 802. In an embodiment, the first patterned conductive layer 804 comprises copper (Cu), although other types of metals may also be used. In an embodiment, the first patterned conductive layer 804 is formed on the panel 802 by initially providing a copper seed layer on the panel 802, and then patterning, plating, resist-stripping and seed-etching the copper layer in a conventional manner. Other conventional fabrication processes may also be used to form the first patterned conductive layer 804. The first patterned conductive layer 804 may constitute the bottom turns of a solenoid inductor, for example, the bottom conductive layer 404 of the solenoid inductor as shown in FIGS. 4 and 5, or the bottom conductive traces of a toroid inductor, for example, the bottom conductive traces 604a, 604b, 604c, . . . of the toroid inductor as shown in FIGS. 6, 7A and 7B.

Referring to FIG. 8A, after the first patterned conductive layer 804 is formed on the panel 802, a first dielectric layer 806 is formed on the first patterned conductive layer 804. The first dielectric layer 806 may be formed by conventional resist-patterning and resist-curing processes, for example, or other conventional processes known to persons skilled in the art. After the first dielectric layer 806 is formed, a magnetic material, for example, a magnetic layer or core 808, is formed on the first dielectric layer 806. The magnetic core 808 may comprise nickel-iron (NiFe), cobalt-zirconium-tantalum (CZT) or another magnetic material.

In an embodiment in which the magnetic core 808 comprises NiFe, the magnetic core 808 may be fabricated by providing an NiFe seed layer on the first dielectric layer 806, and then patterning, plating, resist-stripping and ion-milling the NiFe seed layer in a conventional manner. The NiFe magnetic core 808 may also be formed by patterning, etching and resist-stripping an NiFe seed layer, or by other conventional processes known to persons skilled in the art. In an embodiment in which the magnetic core 808 comprises CZT, it may be formed by sputtering, patterning and etching a CZT layer in a conventional manner.

FIG. 8B illustrates an embodiment of additional steps in the process of making three-dimensional inductors. After the magnetic core 808 is formed on the first dielectric layer 806, a second dielectric layer 810 is formed on the magnetic core 808 such that the magnetic core 808 is covered by the first and second dielectric layers 806 and 810. In an embodiment, the second dielectric layer 810 may be fabricated by conventional resist or PI patterning and curing processes known to persons skilled in the art. After the second dielectric layer 810 is formed, a second patterned conductive layer 812 is formed on the second dielectric layer 810. In an embodiment, the second patterned conductive layer 812 comprises copper (Cu), although other types of metals may also be used.

In an embodiment in which the second patterned conductive layer 812 comprises copper, the second patterned conductive layer 812 may be formed on the second dielectric layer 810 by providing a copper seed layer on the second dielectric layer 810, and then patterning, plating, resist-stripping and seed-etching the copper layer in a conventional manner. Other conventional fabrication processes may also be used to form the second patterned conductive layer 812. The second patterned conductive layer 812 may constitute the top turns of a solenoid inductor, for example, the top conductive layer 406 of the solenoid inductor as shown in FIGS. 4 and 5, or the top conductive traces of a toroid inductor, for example, the top conductive traces 606a, 606b, 606c, . . . of the toroid inductor as shown in FIGS. 6, 7A and 7B. In a further embodiment, a plurality of vias (not shown in the sectional views of FIGS. 8A-8C), such as vias 414 and 416 as shown in FIGS. 4 and 5, are provided in the first and second dielectric layers 806 and 810 to allow side conductors, such as side conductors 408 and 410 in the solenoid inductor of FIGS. 4 and 5, or side conductors 608a, 608b, 608c, . . . in the toroid inductor of FIGS. 6, 7A and 7B, to connect with respective top and bottom conductive traces to form three-dimensional solenoid or toroid inductors.

FIG. 8C illustrates an embodiment of further steps in the process of making three-dimensional inductors. After the second patterned conductive layer 812 is fabricated, a third dielectric layer 814 is formed on the second patterned conductive layer 812. In an embodiment, the third dielectric layer 814 may be formed by conventional dielectric patterning and curing processes, for example. In a further embodiment, a patterned pad layer 816 is formed to provide electrical connections to terminals 818a and 818b of the three-dimensional inductor. The patterned pad layer 816 may be formed by providing a seed layer, such as a seed layer made of nickel (Ni), gold (Au) or another metal, and patterning, pad-plating, resist-stripping and seed-etching the layer in a conventional manner, for example. Other conventional processes may also be used in fabricating the patterned pad layer 816.

While the foregoing disclosure describes illustrative embodiments, it should be noted that various changes and modifications could be made herein without departing from the scope of the appended claims. The functions, steps or actions in the method and apparatus claims in accordance with the embodiments described herein need not be performed in any particular order unless explicitly stated otherwise. Furthermore, although elements may be described or claimed in the singular, the plural is contemplated unless limitation to the singular is explicitly stated.

What is claimed is:

1. A device, comprising:
an interconnect layer having a first surface and a second surface opposite each other;
one or more dies on the first surface of the interconnect layer;
one or more balls on the second surface of the interconnect layer, said one or more balls each having a height perpendicular to the second surface of the interconnect layer and one or more outer surfaces, the outer surfaces of at least some of said one or more balls and the second surface of the interconnect layer forming a landside region; and
one or more three-dimensional inductors comprising one or more solenoids occupying at least a portion of the height of said one or more balls and one or more magnets within the landside region.

2. The device of claim 1, wherein said one or more three-dimensional inductors comprise closely coupled solenoids.

3. The device of claim 1, wherein said one or more magnets comprise cobalt-zirconium-tantalum (CZT).

4. The device of claim 1, wherein said one or more magnets comprise nickel-iron (NiFe).

5. The device of claim 1, wherein said one or more magnets comprise a magnetic layer disposed proximate a portion of at least one of said one or more solenoids.

6. The device of claim 1, wherein said one or more magnets comprise a plurality of magnetic layers disposed proximate a plurality of portions of at least one of said one or more solenoids.

7. The device of claim 1, further comprising a dielectric in the landside region surrounding at least a portion of said one or more inductors.

8. The device of claim 1, wherein said one or more inductors are disposed opposite the die, further comprising one or more conductors connected between the die and said one or more inductors through the interconnect layer.

9. A device, comprising:
an interconnect layer having a first surface and a second surface opposite each other;
one or more dies on the first surface of the interconnect layer;
one or more balls on the second surface of the interconnect layer, said one or more balls each having a height perpendicular to the second surface of the interconnect layer and one or more outer surfaces, the outer surfaces of at least some of said one or more balls and the second surface of the interconnect layer forming a landside region; and
one or more three-dimensional inductors comprising one or more toroids occupying at least a portion of the height of said one or more balls and one or more magnets within the landside region.

10. The device of claim 9, wherein at least one of said one or more toroids surrounds at least one of said one or more balls.

11. The device of claim 9, wherein said one or more magnets comprise cobalt-zirconium-tantalum (CZT).

12. The device of claim 9, wherein said one or more magnets comprise nickel-iron (NiFe).

13. The device of claim 9, wherein said one or more magnets comprise a magnetic layer disposed proximate at least a portion of at least one of said one or more toroids.

14. The device of claim 9, wherein said one or more magnets comprise a plurality of magnetic layers disposed proximate a plurality of portions of at least one of said one or more toroids.

15. The device of claim 9, further comprising a dielectric in the landside region surrounding at least a portion of said one or more inductors.

16. A method of making an integrated circuit package, comprising the steps of:
forming a first patterned conductive layer on a panel;
forming a first dielectric layer on the first patterned conductive layer;
forming a magnet on the first dielectric layer;
forming a second dielectric layer on the magnet; and
forming a second patterned conductive layer on the second dielectric layer, wherein the first patterned conductive layer, the second patterned conductive layer and the magnet together constitute at least a portion of a three-dimensional inductor.

17. The method of claim 16, wherein the first patterned conductive layer and the second patterned conductive layer comprise copper.

18. The method of claim 16, wherein the magnet comprises cobalt-zirconium-tantalum (CZT).

19. The method of claim 16, wherein the magnet comprises nickel-iron (NiFe).

20. The method of claim 16, wherein the panel comprises a substrate.
